(19) United States
(12) Patent Application Publication
(10) Pub. No.: US 2005/0109728 A1
(43) Pub. Date: May 26, 2005

(54) End point detector for etching equipment

(76) Inventor: Sang-Do Oh, Yongin-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 10/974,941

(22) Filed: Oct. 28, 2004

(30) Foreign Application Priority Data
Oct. 29, 2003 (KR) 2003-75748

(51) Int. Cl. C23F 1/00; H01L 21/306; H01B 13/00

(52) U.S. Cl. 216/20

(57) ABSTRACT

The present invention relates to an end point detector for etching equipment. The embodiment of the present invention has a unique feature which allows for a minimal contact between a connector and viewing window. This feature prevents scratches on the surface of the viewing window when the connector is removed or replaced.

### CROSS REFERENCES TO RELATED APPLICATIONS

This application claims the priority of Korean Patent Application No. 2003-75748, filed on 29 Oct. 2003, the contents of which are hereby incorporated by reference in their entirety as if fully set forth herein.

### BACKGROUND OF THE INVENTION

The present invention relates to an end point detector used in etching equipment. More particularly, the present invention relates to an end point detector that minimizes a contact area between a viewing port and an optical cable-fixing connector, which reduces scratches and wear and tear on the surface of a viewing window during removal and replacement of connector.

An end point detector (EPD) is an apparatus applied to a process chamber, specifically an etching chamber, used for a semiconductor device fabrication process.

More specifically, a window is installed over an opening in a wall of an etching chamber, and light emitted or received through the window is transmitted to detection equipment via an optical cable connected between the detection equipment and the window.

The transmitted light is analyzed to monitor processes within the chamber, such as the amount of etching reactants in order to monitor the etching process, i.e., control the end point.

As used herein, the term “end point” refers to the amount of time required to etch and expose a silicon substrate or other films. For detection of light and wavelengths used for end point detection, the optical cable should not be bent or abruptly turned for accurate transmission of light.

FIG. 1 is a cross-section view of conventional etching equipment having an EPD.

The conventional etching equipment has, as illustrated, an electrostatic chuck 2 to hold a wafer by electrostatic force in a process chamber, and electrodes 3 and 4 disposed in an upper portion of the process chamber and on a bottom of electrostatic chuck 2, respectively. In operation, reaction gas is injected between the electrodes to generate plasma.

This configuration also includes a viewing window 5, typically made of a quartz material, installed on a chamber wall 1 of the etching equipment so as to extend over the opening in chamber wall 1. EPD controller (not shown) is installed outside of viewing window 5 to monitor the end point in the process chamber.

Referring to FIG. 2, a bracket 5a is disposed external to, and tightly surrounding, viewing window 5. An optical cable 6 extends from the EPD controller, and at its other end is fixedly inserted into a connector 7, which is removably engaged with bracket 5a.

Typically, with an increase in the number of uses of the etching equipment, residual impurities accumulate in the process chamber, whereupon some of the impurities adhere to a surface of viewing window 5. The impurities on viewing window 5 deteriorate light transmittance and may cause errors in the end point detection. In an attempt to minimize the errors, a periodic check of the equipment as well as a periodic replacement of one or more components of the equipment must be performed.

A method of preventing a viewing window from accumulating impurities is disclosed in Korean Patent Publication No. 0159224 (“End Point Detector for Plasma Etching Equipment”). In addition, a method of preventing damage to a viewing window is described in Korean Patent Laid-Open No. 1999-74934 (“Window Assembly of Chamber Equipment for Fabrication of Semiconductor Device) and U.S. Pat. No. 6,322,660.

Periodic cleaning of the chamber and replacement of components are essential. However, continual removal and replacement of connector 7 from/into bracket 5a leave scratches on the surface of viewing window 5. The scratches on the surface of viewing window 5 cause errors in the EPD wavelength detection.

### SUMMARY OF THE INVENTION

It would therefore be desirable to provide an arrangement that can reduce or eliminate damage, such as scratches, on the surface of a viewing window during removal and replacement of a connector from/into a bracket of the viewing window.

In one aspect of the invention, an end point detector apparatus for etching equipment includes a chamber wall having an opening therein, and a window disposed over the opening, a connector having a first end in the first end of said connector having a recess formed therein in contact with the window, and a bracket connected to the chamber wall around a periphery of the window and engaging the connector.

In another aspect, an end point detector apparatus for etching equipment includes a chamber with a chamber wall having an opening therein, a window disposed over the opening, and a bracket connected to the chamber body around a periphery of the window, a connector adapted to be engaged within the bracket, said connector having a first end adapted to be in contact with the window, the first end of the connector having a recess formed therein, and an optical cable disposed within the connector, said optical cable having a first end adapted to receive light from the chamber via the window.

In yet another aspect, equipment for semiconductor fabrication includes, a process chamber including a chamber wall having an opening therein, a window disposed over the opening in the chamber wall, a bracket connected to the chamber wall around a periphery of the window, and an optical cable connector engaged within the bracket, said connector having a first end in contact with the window, the first end of the connector having a recess formed therein.

### BRIEF DESCRIPTION OF THE DRAWINGS

FIG. 1 is a cross-section view of conventional etching equipment;

FIG. 2 is a cross-section view of a conventional EPD apparatus; and

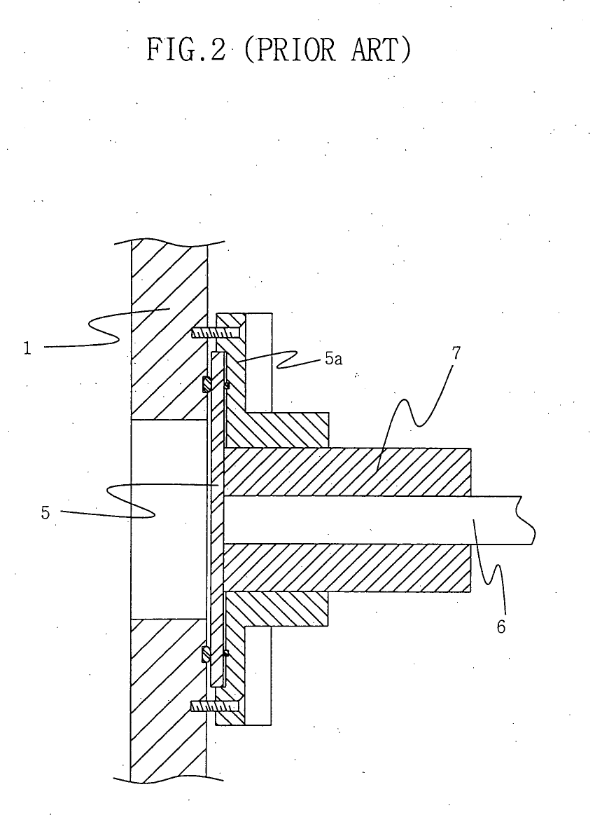

FIG. 3 is a cross-section view of etching equipment having an EPD apparatus according to one of more aspects of the present invention.

FIG. 4 is a cross-section view of etching equipment having an EPD apparatus according to one or more aspects of the present invention without an optical cable inserted therein.

### DETAILED DESCRIPTION

Now, the present invention will be described in detail by way of an embodiment with reference to the accompanying drawings.

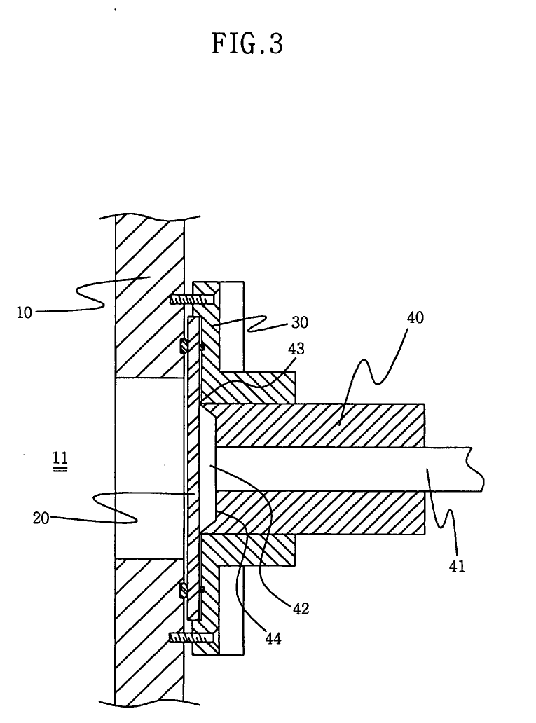

FIG. 3 shows a portion of a process chamber 11 including a chamber wall 10 having an opening formed therein, a viewing window 20 disposed over the opening in the chamber wall 10, a bracket 30 connected to the chamber wall 10 around a periphery of the viewing window 20, a connector 40 engaged within the bracket 30 having a first end 43 in contact with the viewing window 20, and an optical cable 41 disposed within the connector 40 having a first end adapted to receive light from the inside of process chamber 11 by means of the viewing window 20.

Advantageously, the first end 43 of connector 40 is recessed to a predetermined depth to form a recess 42, minimizing the contact area between connector 40 and a viewing window 20.

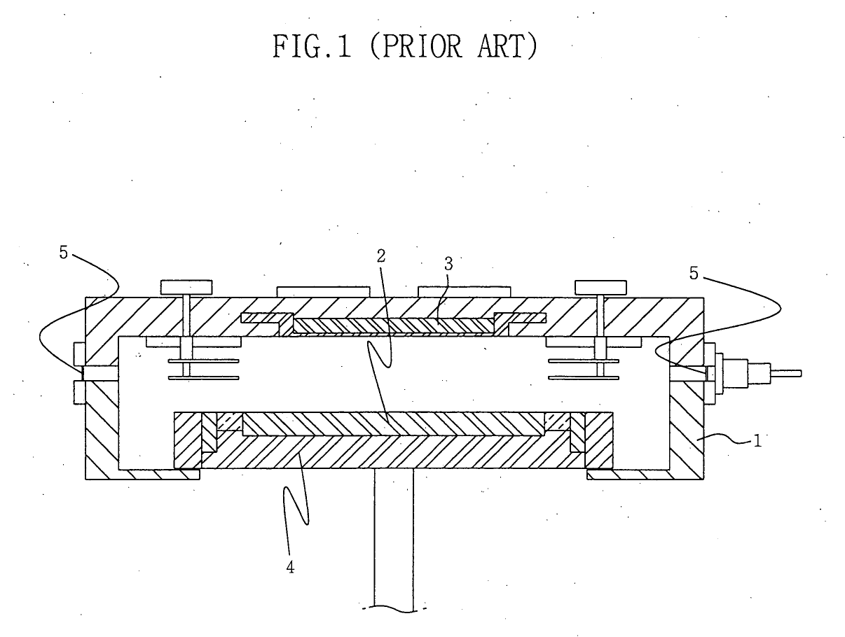

Beneficially, process chamber 11 includes an electrostatic chuck (see FIG. 1) to hold a wafer, and electrodes for generating plasma to etch a pattern on the wafer.

Beneficially, viewing window 20, which is provided on one side of chamber wall 10, is a transparent material, for example a quartz material, to allow the inside of the process chamber 11 to be viewed from the outside.

Bracket 30 is provided on the outside of chamber wall 10 with a profile surrounding viewing window 20. The bracket 30 is tightly welded on the periphery of the opening of the viewing window 20 and in communication with the outer periphery of the viewing window 20 outside of the process chamber 11. Beneficially, bracket 30 is in communication with chamber wall 10 at the periphery of the opening in the chamber wall 10. Beneficially, bracket 30 is in communication with chamber wall 10 by screw connection.

Beneficially, connector 40 is removably engaged within bracket 30, with one end of an optical cable 41 being fixedly inserted into connector 40. With connector 40 engaged into bracket 30, the first end 43 of connector 40 is in contact with viewing window 20.

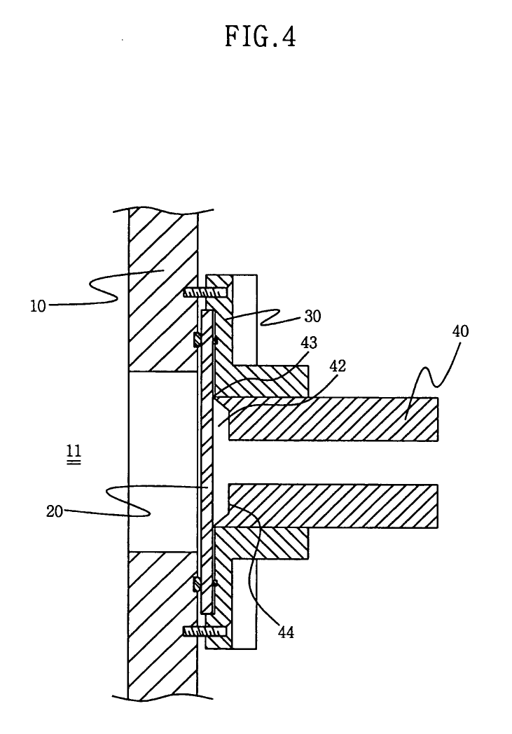

Advantageously, a first end 43 of connector 40 in contact with viewing window 20 is horizontally recessed to a predetermined area to minimize the contact area between connector 40 and viewing window 20. Beneficially, recess 42 extends from the first end 43 of the connector 40 to a bottom interior surface 44 of the connector 40. As shown in FIGS. 3 and 4, the recess 42 is beneficially concave. Optionally, the recess 42 may have a stepped shape.

Beneficially, the diameter of recess 42 of the connector 40 is larger than the diameter of optical cable 41, thereby forming the bottom interior surface 44. Beneficially, a surface area of a portion of connector 40 that contacts viewing window 20 is less than a surface area of the first end of an optical cable 41 that confronts and is spaced apart from the window 20. Also beneficially, the first end of the optical cable 41 is positioned in a same plane as the bottom interior surface 44 of the connector 40.

FIG. 4 illustrates a case where optical cable 41 is not inserted in connector 40, helping to better illustrate recess 42.

Now, the operation of the arrangement of FIGS. 3 and 4 will be described as follows.

Advantageously, first end connector 40 in contact with viewing window 20 is recessed to a predetermined area and predetermined depth to form recess 42, thereby minimizing the contact area between connector 40 and viewing window 20.

An end point detector monitors the end point of an etching process by passing light between the process chamber and an EPD controller through viewing window 20 via optical cable 41 inserted in the connector 40.

Particularly, recess 42 of the connector 40 is formed over a portion of viewing window 20, preventing impact and scratches caused by the engagement of connector 40.

In this way, scratches can be minimized or avoided on the surface of viewing window 20 when the first end of connector 40 is removed from and replaced into bracket 30.

While the present invention has been described in connection with what is presently considered to be the most practical and preferred embodiment, it is to be understood that the present invention is not limited to the disclosed embodiment, but on the contrary, is intended to cover various modifications and equivalent arrangements included within the spirit and scope of the appended claims.

1. An end point detector apparatus for etching equipment including a chamber with a chamber wall having an opening therein, a window disposed over the opening, and a bracket connected to the chamber body around a periphery of the window, said apparatus comprising:
a connector adapted to be engaged within the bracket, said connector having a first end adapted to be in contact with the window, the first end of the connector having a recess formed therein; and
an optical cable disposed within the connector, said optical cable having a first end separated and spaced apart from the window and being adapted to receive light from the chamber via the window.

2. The apparatus of claim 1, wherein the recess extends to a bottom interior surface of the connector that is adapted to be separated and spaced apart from the window and substantially parallel to the window.

3. The apparatus of claim 1, wherein the first end of the optical cable extends to substantially a same plane as the bottom interior surface of the connector.

4. The apparatus of claim 1, wherein a surface area of a portion of the connector adapted to be in contact with the window is less than a surface area of the first end of the optical cable.

5. The apparatus of claim 1, wherein the connector is adapted to be removably engaged within the bracket.

6. The apparatus of claim 1, wherein the recess is concave.

7. The apparatus of claim 1, wherein the recess has a stepped shape.

8. Equipment for semiconductor fabrication, comprising:
a process chamber including a chamber wall having an opening therein;
a window disposed over the opening in the chamber wall;
a bracket connected to the chamber wall around a periphery of the window; and
an optical cable connector engaged within the bracket, said connector having a first end in contact with the window, the first end of the connector having a recess formed therein.

9. The apparatus of claim 8, wherein the recess extends to a bottom interior surface of the optical cable connector that is separated and spaced apart from the window.

10. The equipment of claim 8, further comprising an optical cable disposed within the optical cable connector, said optical cable having a first end adapted to receive light from the chamber via the window, the first end of the optical cable being separated and spaced apart from the window.

11. The apparatus of claim 10, wherein the recess extends to a bottom interior surface of the optical cable connector that is separated and spaced apart from the window, and wherein the first end of the optical cable extends to substantially a same plane as the bottom interior surface of the optical cable connector.

12. The apparatus of claim 10, wherein a surface area of a portion of the optical cable connector in contact with the window is less than a surface area of the first end of the optical cable.

13. The apparatus of claim 10, wherein the connector is adapted to be removably engaged within the bracket.

14. An end point detector apparatus for etching equipment including a chamber wall having an opening therein, the apparatus, comprising:
a window disposed over the opening;
a connector having a first end in contact with the window, the first end of said connector having a recess formed therein; and
a bracket connected to the chamber wall around a periphery of the window and engaging the connector.

15. The apparatus of claim 14, further comprising an optical cable disposed in the connector, wherein an end of the optical cable is separated and spaced apart from the window.

16. The apparatus of claim 15, wherein an area of the connector contacting the window is smaller than an area of an end of the optical cable separated and spaced apart from the window.

17. The apparatus of claim 14, wherein the recess extends to a bottom interior surface of the connector that is spaced apart from and parallel to the window.

18. The apparatus of claim 14, wherein the recess is concave.

19. The apparatus of claim 14, wherein the recess is stepped.
